(19) United States
(12) Patent Application Publication
(10) Pub. No.: US 2010/0068881 A1
(43) Pub. Date: Mar. 18, 2010

(54) Method of forming metallization in a semiconductor device using selective plasma treatment

(76) Inventors: Joo-ho Kang, Seoul (KR); Matsuda Tsukasa, Seongnam-si (KR); Yong-chul Lee, Anyang-si (KR); Hyung-sik Hong, Suwon-si (KR); Sang-yeob Cha, Seoul (KR); Tae-hong Ha, Hwaseong-si (KR)

Correspondence Address: LEE & MORSE, P.C., 3141 FAIRVIEW PARK DRIVE, SUITE 500, FALLS CHURCH, VA, 22042, US

(21) Appl. No.: 12/458,676

(22) Filed: Jul. 20, 2009

(30) Foreign Application Priority Data
Sep. 18, 2008 (KR) 10-2008-0091617

(51) Int. Cl. H01L 21/768

(52) U.S. Cl. 438/653; 438/675; 257/E21.584; 257/E21.586

(57) ABSTRACT

A method of forming metallization in a semiconductor device, including forming an interlayer insulation layer on a semiconductor layer, forming a hole in the interlayer insulation layer by removing a portion of the interlayer insulation layer, forming a metal seed layer in the hole and on an upper surface of the interlayer insulation layer, such that the metal seed layer includes a first portion on the upper surface of the interlayer insulation layer, a second portion on an upper side surface of the hole, and a third portion on central and lower side surfaces of the hole, selectively plasma-treating a portion of the metal seed layer, forming a metal layer on the metal seed layer to fill the hole, and forming metallization by polishing the metal layer.

### BACKGROUND

1. Field of the Invention

Example embodiments relate to a method of forming metallization in a semiconductor device. More particularly, example embodiments relate to a method of forming metallization in a semiconductor device using a selective plasma process.

2. Description of the Related Art

Interconnections electrically connected to a substrate or a semiconductor device formed on the substrate may be generally formed, e.g., using a damascene process. In the damascene process, a trench or a hole may be formed in an insulating layer, and the trench or hole may be filled with metal, e.g., copper, to form the interconnection. However, as a size of the semiconductor device is reduced, undesired defects may occur, e.g., void formation in the trench or hole during filling thereof, thereby reducing the reliability of the semiconductor device.

### SUMMARY

Embodiments are therefore directed to a method of forming metallization in a semiconductor device, which substantially overcomes one or more of the problems due to the limitations and disadvantages of the related art.

It is therefore a feature of an embodiment to provide metallization in a semiconductor device with reduced voids therein by using selective plasma.

At least one of the above and other features and advantages may be realized by providing a method of forming metallization in a semiconductor device, the method including forming an interlayer insulation layer on a semiconductor layer, forming a hole in the interlayer insulation layer by removing a portion of the interlayer insulation layer, forming a metal seed layer in the hole and on an upper surface of the interlayer insulation layer, such that the metal seed layer includes a first portion on the upper surface of the interlayer insulation layer, a second portion on an upper side surface of the hole, and a third portion on central and lower side surfaces of the hole, selectively plasma-treating a portion of the metal seed layer, forming a metal layer on the metal seed layer to fill the hole, and forming metallization by polishing the metal layer.

In some embodiments of the inventive concept, in the plasma treatment, the metal seed layer formed on the upper surface of the interlayer insulation layer may be plasma-treated. In the plasma treatment, an upper portion of the metal seed layer, which is formed on the side surfaces of the interlayer insulation layer exposed by the hole, may be plasma-treated. Selectively plasma-treating a portion of the metal seed layer may include plasma-treating only the first and second portions of the metal seed layer before forming the metal layer.

In some embodiments of the inventive concept, the plasma treatment may be performed using a nitrogen containing gas. The nitrogen containing gas may include N₂, N₂H₄, NH₃, or a mixture thereof. The nitrogen containing gas may have a flux in a range of about 1 sccm to about 50 sccm. The plasma treatment may be performed using an inert gas with a flux in a range of about 1 sccm to about 20 sccm.

In some embodiments of the inventive concept, the plasma treatment may be performed with a radio frequency (RF) voltage in a range of about 1 W to about 2000 W. In some embodiments of the inventive concept, the plasma treatment may be performed without applying a bias voltage to the semiconductor layer, or by applying a bias voltage of 250 W or less to the semiconductor layer.

In some embodiments of the inventive concept, the method may further include forming a barrier layer on the semiconductor layer, between the forming of the hole and the forming of the metal seed layer. The barrier layer may include Ta, TaN, or both.

In some embodiments of the inventive concept, the metal seed layer, the metal layer, or both may include Cu, Pt, Pd, Ni, Au, Ag, Ru, or an alloy thereof. In some embodiments of the inventive concept, the metal layer may be formed using an electroplating process. In some embodiments of the inventive concept forming the interlayer insulation layer may include sequentially stacking first and second interlayer insulation layers on the semiconductor layer, forming the hole may include sequentially forming a via and a trench in the first and second interlayer insulation layers, respectively, wherein the metal seed layer may be formed to include the first portion on upper surfaces of the first and second interlayer insulation layers, the second portion on upper side surfaces of each of the trench and via, and the third portion on central and lower side surfaces of each of the trench and via.

At least one of the above and other features and advantages may also be realized by providing a method of forming metallization in a semiconductor device, the method including forming a hole by removing a portion of an interlayer insulation layer formed on a semiconductor layer, forming a metal seed layer on a bottom surface and side surfaces of the hole, which is formed in the interlayer insulation layer, and on an upper surface of the interlayer insulation layer the interlayer insulation layer, plasma-treating a portion of the metal seed layer, forming a metal layer on the metal seed layer to fill the hole, and forming metallization by polishing the metal layer, wherein the plasma treatment is performed using a nitrogen containing gas having a flux in a range of about 1 sccm to about 50 sccm, and inert gas having a flux in a range of about 1 sccm to about 20 sccm, wherein the plasma treatment is performed with an RF voltage in a range of about 1 W to 2000 W, wherein the plasma treatment is performed without applying a bias voltage to the semiconductor layer or by applying a bias voltage of 250 W or less to the semiconductor layer.

At least one of the above and other features and advantages may also be realized by providing a method of forming metallization in a semiconductor device, the method including forming a trench and a via by removing portions of interlayer insulation layers, which are formed on a semiconductor layer, forming metal seed layers on side surfaces of the interlayer insulation layers, which are exposed by the trench and the via, and on upper surfaces of the interlayer insulation layers, plasma-treating a portion of the metal seed layers, forming a metal layer on the metal seed layer to fill the via and the trench, and forming metallization by polishing the metal layer.

In some embodiments of the inventive concept, in the plasma treatment, the metal seed layers formed on the upper surfaces of the interlayer insulation layer may be plasma-treated. In the plasma treatment, upper portions of the metal seed layers formed on the side surfaces of the interlayer insulation layers, which are exposed by the trench and the via, may be plasma-treated.

In some embodiments of the inventive concept, the plasma treatment may be performed using a nitrogen containing gas having a flux in a range of about 1 sccm to about 50 sccm, and inert gas having a flux in a range of about 1 sccm to about 20 sccm, wherein the plasma treatment is performed with an RF voltage in a range of about 1 W to about 2000 W, wherein the plasma treatment is performed without applying a bias voltage to the semiconductor layer or by applying a bias voltage of 250 W or less to the semiconductor layer.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1A through 1G illustrate cross-sectional views of steps in a method of forming metallization according to embodiments; and

FIGS. 2A through 2G illustrate cross-sectional views of steps in a method of forming metallization according to other embodiments.

### DETAILED DESCRIPTION

Korean Patent Application No. 10-2008-0091617, filed on Sep. 18, 2008, in the Korean Intellectual Property Office, and entitled: “Method of Forming Metallization in Semiconductor Device Using Selective Plasma Treatment,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will be understood that when an element, such as a layer, a region, or a substrate, is referred to as being “on,” “connected to,” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. In addition, it will also be understood that when a layer is referred to as being “between” two layers, it can be the only layer between the two layers, or one or more intervening layers may also be present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

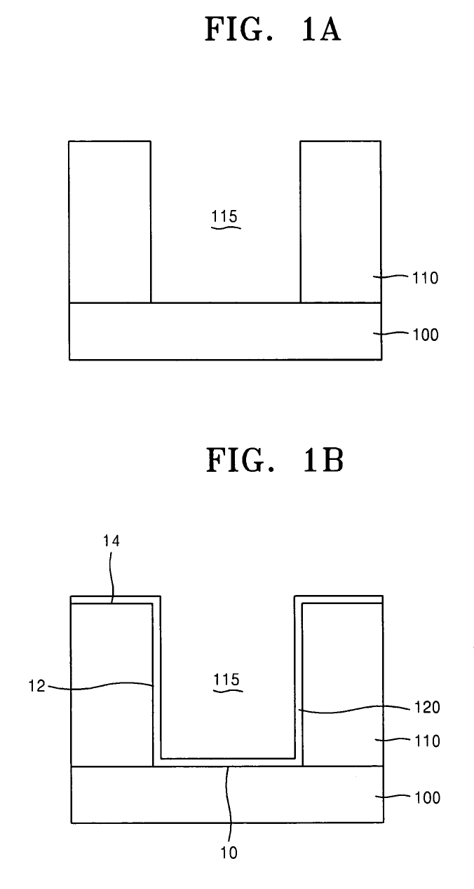

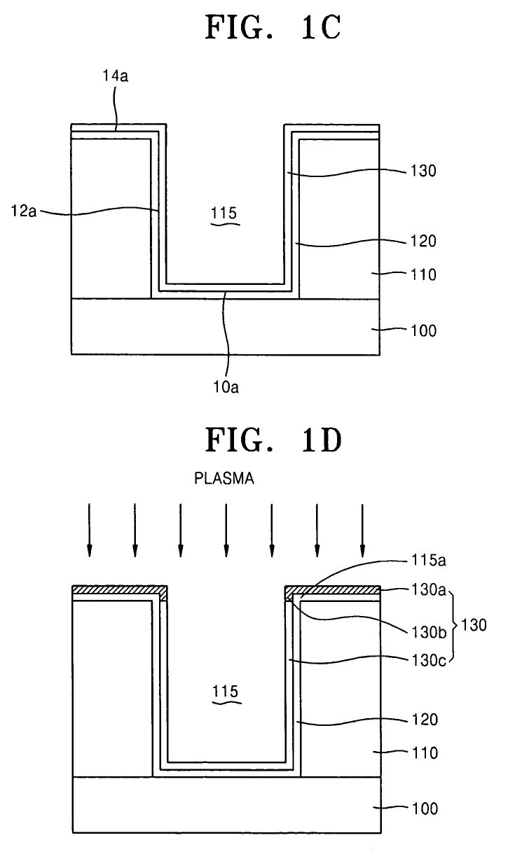

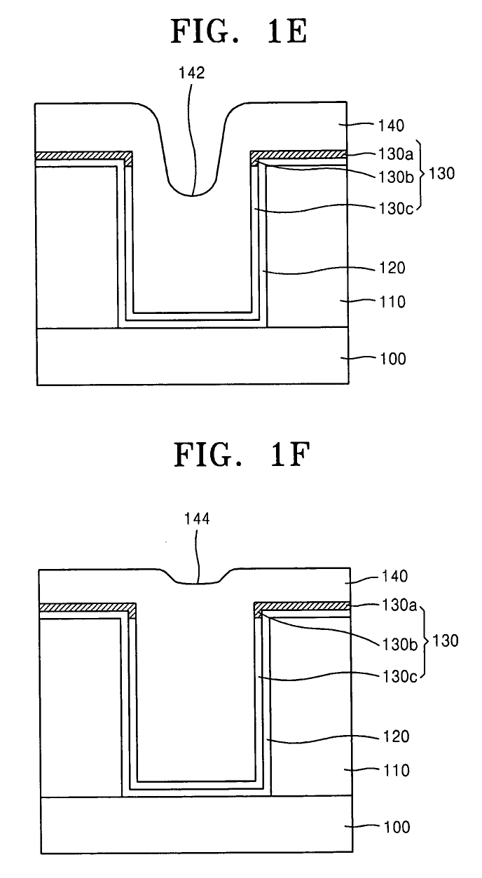

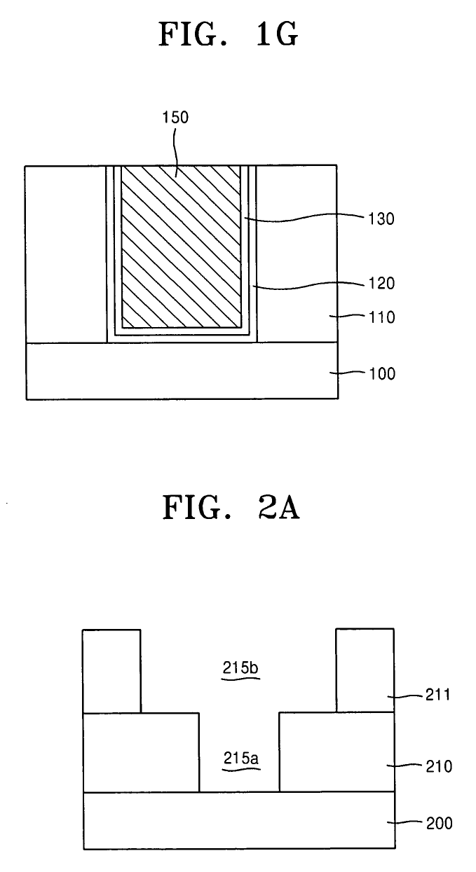

FIGS. 1A through 1G illustrate cross-sectional views of steps in a method of forming metallization, e.g., a metal contact, according to an embodiment. The method in FIGS. 1A through 1G illustrates application of an example embodiment to a single damascene process.

Referring to FIG. 1A, a semiconductor layer 100 may be prepared. The semiconductor layer 100 may be a substrate, an epitaxial layer, or a silicon on insulator (SOI). In addition, the semiconductor layer 100 may include a semiconductor device (not shown), e.g., a gate structure or an interconnection. An interlayer insulation layer 110 may be formed on the semiconductor layer 100. A hole 115 may be formed by removing a portion of the interlayer insulation layer 110, e.g., an upper surface of the semiconductor layer 100 may be exposed through the hole 115. The hole 115 may be formed, e.g., using any suitable etching process.

Referring to FIG. 1B, a barrier layer 120 may be formed, e.g., conformally, on an entire surface including the hole 115. In other words, the barrier layer 120 may be formed on, e.g., directly on, the exposed upper surface 10 of the semiconductor layer 100, side surfaces 12 of the interlayer insulation layer 110, and an upper surface 14 of the interlayer insulation layer 110. In this respect, it is noted that the upper surface 14 of the interlayer insulation layer 110 refers to a surface of the interlayer insulation layer 110 that is substantially parallel to the upper surface 10 of the semiconductor layer 100 and faces away from the semiconductor layer 100. Similarly, side surfaces 12 of the interlayer insulation layer 110 refer to inner sidewalls of the hole 115 that extend between the upper surface 14 of the interlayer insulation layer 110 and the upper surface 10 of the semiconductor layer 100. The barrier layer 120 may be formed, using, e.g., a physical vapor deposition (PVD), a chemical vapor deposition (CVD), a plasma enhanced deposition CVD (PECVD), or an atomic layer deposition (ALD). Formation of the barrier layer 120 may be optional.

When the example embodiment include formation of the barrier layer 120, the barrier layer 120 may be formed under a pressure of about 5 mTorr to about 50 mTorr. The barrier layer 120 may be conductive and may prevent diffusion of metal into the semiconductor layer 100 or the interlayer insulation layer 110, e.g., may prevent or substantially minimize diffusion of copper included in a metal seed layer (130, refer to FIG. 1C) or in a metal layer (140, refer to FIG. 1E) formed in subsequent processes into the semiconductor layer 100 or the interlayer insulation layer 110. The barrier layer 120 may be formed of, e.g., one or more of Ta, TaN, Ti, TiN, W, WN, or a combination thereof (for example, alloy or a stacked structure of the above materials). For example, the barrier layer 120 may be formed by forming a layer including TaN on the semiconductor layer 100 and the interlayer insulation layer 110, and then forming a layer including Ta on the TaN layer. However, the present inventive concept is not limited to the above example.

Referring to FIG. 1C, the metal seed layer 130 may be formed, e.g., conformally, on the barrier layer 120. That is, the metal seed layer 130 may be formed on, e.g., directly on, a bottom surface 10a and side surfaces 12a of the barrier layer 120 in the hole 115 and on, e.g., directly on, an upper surface 14a of the barrier layer 120. The metal seed layer 130 may include, e.g., one or more of Cu, Pt, Pd, Ni, Au, Ag, Ru, or an alloy thereof. However, the present inventive step is not limited to the above example. The metal seed layer 130 may be formed using, e.g., the PVD, CVD, PECVD, or ALD processes. The metal seed layer 130 may facilitate formation of the metal layer 140 in a subsequent process, as will be described in more detail below with reference to FIG. 1E.

Referring to FIG. 1D, a portion of the metal seed layer 130 may be plasma-treated with plasma, i.e., selectively plasma-treated. As illustrated in FIG. 1D, the portion of the metal seed layer 130 treated with plasma may include an upper surface 130a of the metal seed layer 130, i.e., a portion of the metal seed layer 130 overlapping the upper surface 14 of the interlayer insulation layer 110. As further illustrated in FIG. 1D, the portion of the metal seed layer 130 treated with plasma may include an upper portion 130b of the metal seed layer 130, i.e., a portion of the metal seed layer 130 on an uppermost part of the side surface 12 of the interlayer insulation layer 110 and contacting the upper surface 130a. For example, the upper portion 130b of the metal seed layer 130 may extend from the upper surface 130a into the hole 115 along the side surface 12 to a predetermined depth, so the upper surface 130a and the upper portion 130b may overlap, e.g., completely cover, upper corner 115a of the hole 115. For example, the upper surface 130a and the upper portion 130b may define a rotated L-shaped cross section to cover the upper corner 115a.

For example, as illustrated in FIG. 1D, only the upper surface 130a and the upper portion 130b of the metal seed layer 130 may be plasma-treated, so an inner portion 130c of the metal seed layer 130 may not be plasma-treated. It is noted that hatching is used in FIG. 1D to indicate the plasma-treated portions of the metal seed layer 130, i.e., the upper surface 130a and the upper portion 130b. It is further noted that the inner portion 130c of the metal seed layer 130 refers to a portion of the metal seed layer 130 inside the hole 115, with the exception of the upper portion 130b. For example, a length of the inner portion 130c in the hole 115 may be substantially longer than a length of the upper portion 130b in the hole 115, so a majority depth of the hole 115 may include the inner portion 130c.

In the plasma treatment process, any suitable plasma apparatus may be used. In addition, a remote plasma technology, i.e., a technique including plasma generated apart from the semiconductor layer 100, may be applied.

The plasma treatment process may be performed using gas including nitrogen, i.e., a nitrogen containing gas. For example, the nitrogen containing gas may include N₂, N₂H₄, NH₃, or a mixture thereof. When the metal seed layer 130 is deposited on the semiconductor substrate 100, the metal seed layer 130 may include dangling bonds, i.e., surface defects causing an unstable energy state of the surface. When the portion of the metal seed layer 130, i.e., the upper surface 130a and the upper portion 130b, is treated with plasma, atoms or ions, e.g., nitrogen atoms or nitrogen ions activated by the plasma, may interact with the dangling bonds on the upper surface 130a and the upper portion 130b of the metal seed layer 130, i.e., combine with the surface defects. Accordingly, the unstable energy state of the surface of the metal seed layer 130, i.e., a surface of the upper surface 130a and the upper portion 130b, may be stabilized by the plasma treatment, e.g., by the nitrogen atoms or nitrogen ions, into a metastable state, rather than forming an insulating layer such as a nitride layer. Such a metastable state may disappear within a few days. In addition, hydrogen atoms or hydrogen ions may combine with the surface of the metal seed layer 130 to generate the dangling bonding.

Processing conditions of the plasma treatment process may be controlled, so that only the upper surface 130a and the upper portion 130b of the metal seed layer 130 may be plasma-treated. Accordingly, the nitrogen atoms or nitrogen ions may interact only with, i.e., may be bonded only to, the upper surface 130a and the upper portion 130b of the metal seed layer 130. Therefore, after the selective plasma treatment of the metal layer seed 130, a region defined by the upper surface 130a and the upper portion 130b may be at a metastable state. Thus, a subsequent metal deposition, i.e., to form the metal layer 140, on such a region may be slow due to reduced reactivity thereof. In contrast, when conventional upper surface and portion of a metal seed layer are not plasma-treated, i.e., not stabilized by nitrogen atoms or ions into a metastable state, a metal layer formed subsequently thereon, e.g., on upper corners of a hole, may be dominantly formed, e.g., on the upper corner of the hole. The dominant formation, e.g., relatively fast formation due to an unstable energy state of the metal seed layer, of the metal layer on the conventional upper surface and portion of the metal seed layer may form a protrusion (or overhang) thereon. Such a protrusion (or overhang) may at least partially extend into the hole, so subsequent deposition of metal in the hole may be non-uniform, e.g., include voids.

Therefore, selective plasma-treatment of predetermined portions of the metal seed layer 130 according to example embodiments may facilitate control of rate of formation of a metal layer in a subsequent process according to the predetermined portions. In other words, plasma treatment of the upper surface and portion 130a and 130b of the metal seed layer 130 before metal deposition thereon may stabilize surface energy thereof, so metal layer formation on the plasma-treated portions of the metal seed layer 130 may be slower, as compared to metal layer formation on non plasma-treated portions, i.e., inner portions 130c, of the metal seed layer 130.

The processing conditions of the selective plasma treatment will be described as follows. The nitrogen containing gas used in the plasma treatment may have a flux in a range of about 1 sccm to about 50 sccm. The plasma treatment may include an inert gas, e.g., one or more of argon gas, krypton gas, xenon gas, and so forth, in addition to the nitrogen containing gas. The inert gas may have a flux in a range of about 1 sccm to about 20 sccm. In addition, the plasma treatment may be performed with a radio frequency (RF) power of about 1 W to about 2000 W. For example, the plasma treatment may be performed without applying a bias voltage to the semiconductor layer 100. In another example, the plasma treatment may be performed after applying a bias voltage of about 250 W or less to the semiconductor layer 100, i.e., a bias voltage that is smaller than a bias voltage in a conventional plasma treatment process by about a few kW to about tens of kW. In addition, the plasma treatment may be performed at a temperature range of about (−50)° C. to about 50° C., and at a pressure of about 8 mTorr or less.

Referring to FIG. 1E, the metal layer 140 may be formed on the metal seed layer 130 to fill the hole 115. For example, as illustrated in FIG. 1E, the metal layer 140 may be formed to fill, e.g., completely fill, the hole 15 and to extend to a predetermined thickness on the upper surface 130a of the metal seed layer 130. The metal layer 140 may be formed using, e.g., an electroplating method. The metal layer 140 may be formed of a substantially same material as that of the metal seed layer 130. For example, the metal layer 140 may include one or more of Cu, Pt, Pd, Ni, Au, Ag, Ru, or an alloy thereof. As discussed previously with reference to FIG. 1D, since only the upper surface and portion 130a and 130b are plasma-treated and are at a metastable energy state, formation of the metal layer 140 on the plasma-treated regions 130a and 130b of the metal seed layer 130 may be slower than that on the inner portion 130c that is not plasma-treated. Therefore, since formation of the metal layer 140 is relatively fast from the bottom surface of the hole 115, i.e., in regions surrounded by the inner portion 130c, and slows down at the upper surface and portion 130a and 130b, generation of the protrusion (or overhang) may be prevented or substantially minimized. Thus, occurrence of a void in the hole 115 may be prevented or substantially minimized when forming the metal layer 140. Therefore, a gap-fill property may be improved.

If the metal layer 140 includes a relatively large contraction portion 142 on a region corresponding to a central portion of the hole 115, e.g., as illustrated in FIG. 1E, a reflow process may be subsequently performed. For example, a relatively large contraction portion 142 may be defined when a distance between a bottom of the contraction portion 142 and the upper surface 10 of the semiconductor layer 100 is smaller than a distance between an upper surface 14 of the interlayer insulation layer 110 or an upper surface 130a and the upper surface 10 of the semiconductor layer 100.

Referring to FIG. 1F, the metal layer 140 may be heated to perform the reflow process, so the contraction portion 142 may be filled. After performing the reflow process, a reflowed contraction portion 144 may be substantially smaller than the contraction portion 142, e.g., at a substantially same level or higher than the upper surface 14 of the interlayer insulation layer 110 or the supper surface 130a of the metal seed layer 130. Any suitable reflow process may be used.

Referring to FIG. 1G, the metal layer 140 may be polished, e.g., using a chemical mechanical polishing (CMP) process to form a metallization 150. In the above embodiment, the metallization 150 may be changed according to the bias voltage, the flux of nitrogen gas, and the flux of inert gas. For example, as the bias voltage increases, the flux of the nitrogen gas may increase (or the flux of the inert gas may decrease), the metallization 150 may be degraded.

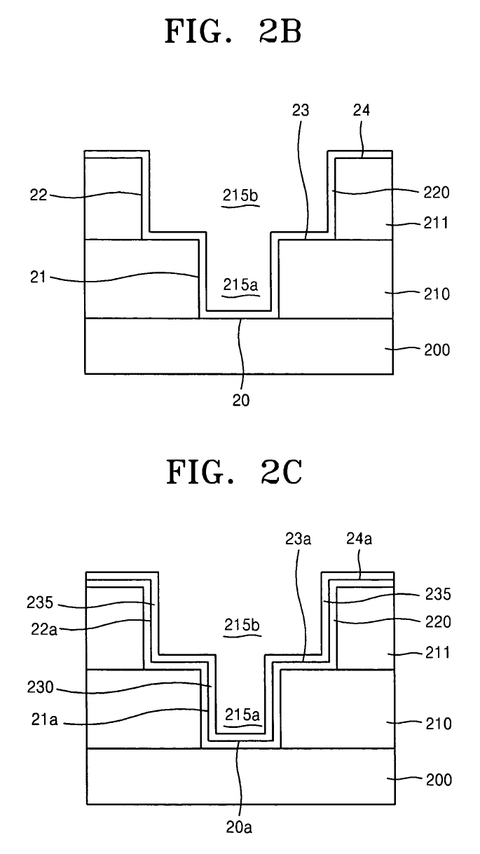

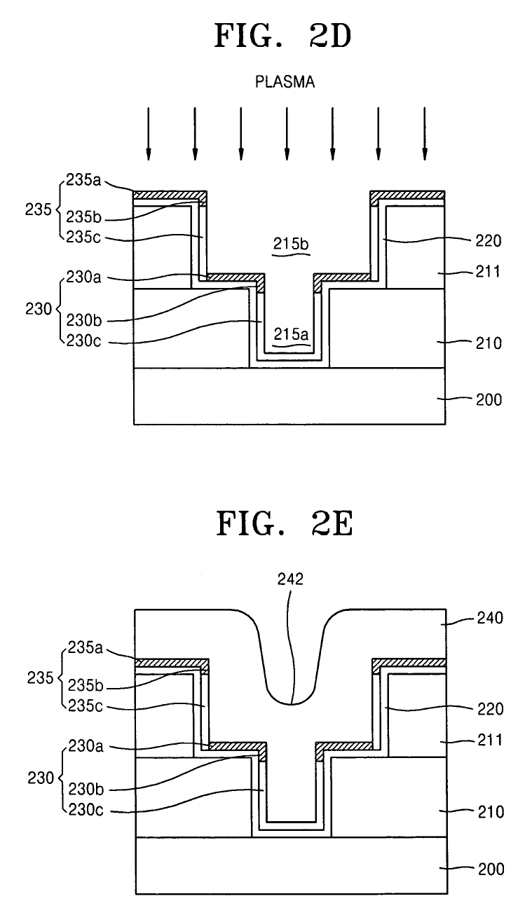

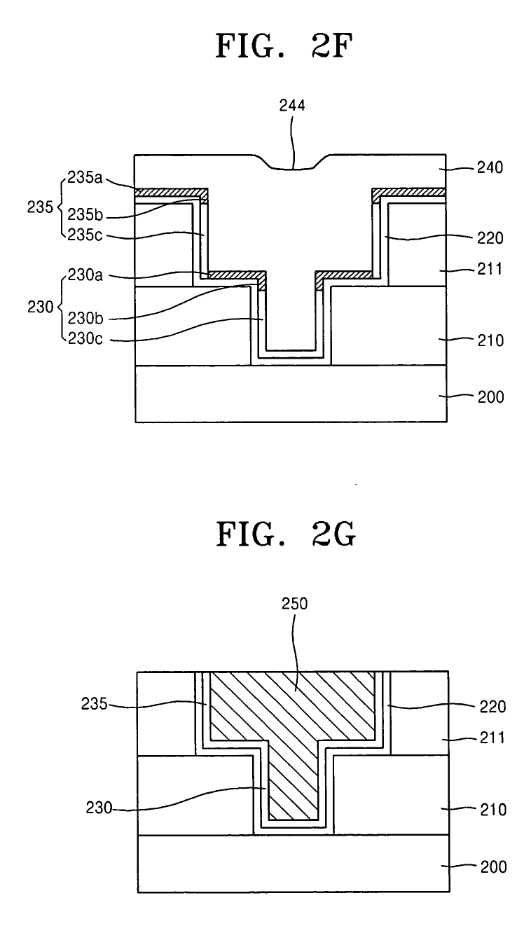

FIGS. 2A through 2G illustrate cross-sectional views of steps in a method of forming metallization according to another embodiment. The method in FIGS. 2A through 2G illustrates application of an example embodiment to a dual damascene process. For convenience, detailed descriptions of same elements described previously with reference to FIGS. 1A through 1G will not be repeated.

Referring to FIG. 2A, a semiconductor layer 200 may be prepared. A first interlayer insulation layer 210 and a second interlayer insulation layer 211 may be formed, e.g., sequentially, on the semiconductor layer 200. A via 215a and a trench 215b may be formed by removing portions of the first and second interlayer insulation layers 210 and 211. The via 215a and the trench 215b may be formed using, e.g., any suitable etching process. For example, the via 215a and the trench 215b may be formed using, e.g., a trench first via last (TFVL) or a via first trench last (VFTL) process. An upper surface of the semiconductor layer 200 may be exposed by the via 215a and the trench 215b.

Referring to FIG. 2B, a barrier layer 220 may be, e.g., optionally, formed on an entire surface including the via 215a and the trench 215b, e.g., on the exposed upper surface 20 of the semiconductor layer 200, side surfaces 21 and 22 of respective first and second interlayer insulation layers 210 and 211, and upper surfaces 23 and 24 of respective first and second interlayer insulation layers 210 and 211. The barrier layer 220 may be formed using a substantially same method for forming the barrier layer 120 described previously with reference to FIG. 1B. The barrier layer 220 may be formed of a substantially same material as that of the barrier layer 120 described previously with reference to FIG. 1B, e.g., Ta, TaN, Ti, TiN, W, WN, Ru, or a combination thereof (for example, an alloy or a stacked structure of these materials). In addition, the barrier layer 220 may have the same functions as those of the barrier layer 120 described previously with reference to FIG. 1B.

Referring to FIG. 2C, first and second metal seed layers 230 and 235 may be formed on the barrier layer 220. That is, the first and second metal seed layers 230 and 235 may be formed on a bottom surface 20a, side surfaces 21a and 22a, and upper surfaces 23a and 24a of the barrier layer 220 in the via 215a and the trench 215b. For example, the first metal seed layer 230 may be formed on the upper surface 20 of the semiconductor layer 200 and on side and upper surfaces 21 and 23 of the first interlayer insulation layer 210, and the second metal seed layer 235 may be formed on side and upper surfaces 22 and 24 of the second interlayer insulation layer 211. The first and second metal seed layers 230 and 235 may have the same functions as the metal seed layer 130 described previously with reference to FIG. 1C, and may be formed of the same material described previously with reference to FIG. 1C, e.g., one or more of Cu, Pt, Pd, Ni, Au, Ag, Ru, or an alloy thereof.

Referring to FIG. 2D, a portion of the first and second metal seed layers 230 and 235 may be plasma-treated. For example, first and second upper surfaces 230a and 235a of the first and second metal seed layers 230 and 235, i.e., portions formed on respective upper surfaces of the first and second interlayer insulation layers 210 and 211, may be plasma-treated. In addition, first and second upper portions 230b and 235b of the first and second metal seed layers 230 and 235, i.e., portions on respective side surfaces 21 and 22 of the first and second interlayer insulation layers 210 and 211 exposed by the via 215a and the trench 215b, may be plasma-treated. First and second inner portions 230c and 235c of the first and second metal seed layers 230 and 235 may not be plasma-treated. In FIG. 2D, the plasma-treated portions of the first and second metal seed layers 230 and 235 are indicated by hatching. Optionally, the second inner region 235c of the second metal seed layer 235 may be plasma-treated. It is noted that the structure of the first and second upper portions 230b and 235b relative to the respective structures of the upper surfaces 230a and 235a is substantially the same as the relative structures of the upper surface and portion 130a and 130b described previously with reference to FIG. 1D.

The plasma treatment process may be performed using a nitrogen containing gas, e.g., N₂, N₂H₄, NH₃, or a mixture thereof. The processing conditions of the selective plasma treatment will be described as follows. The nitrogen containing used in the plasma treatment process may have a flux of about 1 sccm to about 50 sccm. In addition, the plasma treatment process may be performed using an inert gas, e.g., one or more of argon gas, krypton gas, or xenon gas, and so forth, with the gas including nitrogen. The inert gas may have a flux in a range of about 1 sccm to about 20 sccm. In addition, the plasma treatment process may be performed with an RF voltage in a range of about 1 W to about 2000 W. Also, the plasma treatment may be performed without applying a bias voltage to the semiconductor layer 200. Otherwise, the plasma treatment may be performed after applying a bias voltage of about 250 W or less to the semiconductor layer 200. In addition, the plasma treatment may be performed at a temperature range of about (−50)° C. to about 50° C., and at a pressure of about 8 mTorr or less.

Referring to FIG. 2E, a metal layer 240 may be formed on the first and second metal seed layers 230 and 235 to fill the via 215a and the trench 215b. The metal layer 240 may be formed, e.g., using any suitable electroplating process. The metal layer 240 may be formed of the same material as the first and second metal seed layers 230 and 235. For example, the metal layer 240 may include one or more of Cu, Pt, Pd, Ni, Au, Ag, Ru, or an alloy thereof. The formation of the metal layer 240 may be relatively slower on the plasma treated portions 230a, 230b, 235a, and 235b than that on portions 230c and 235c, which are not plasma-treated. Therefore, generation of a protrusion (or overhang) during formation of the metal layer 240 in the via 215a and trench 215b may be prevented or substantially minimized. Thus, an occurrence of a void in the via 215a and the trench 215b may be prevented or substantially minimized. Therefore, a gap-fill property may be improved.

If the metal layer 240 includes a contraction portion 242 on a region corresponding to the central portion of the trench 215b, e.g., when a lower surface of the contraction portion 242 is at a lower level than that of the second interlayer insulation layer 211 or the first metal seed layer 230, a reflow process may be subsequently performed. Referring to FIG. 2F, the metal layer 240 may be heated to perform the reflow process, and thus the contraction portion 242 may be filled.

As further illustrated in FIG. 2F, after performing the reflow process, a reflowed contraction portion 244 may be at a substantially same level as or at a higher level than the second interlayer insulation layer 211 or the first metal seed layer 230. For example, a lower surface of the contraction portion 242 may be at a substantially higher level than the second upper surface 2325a of the second metal seed layer 235.

Referring to FIG. 2G, the metal layer 240 may be polished, e.g., using the CMP process to form metallization 250. For example, the metal layer 240 may substantially uniformly fill both the via 215a and the trench 215 with substantially high step coverage. For example, as further illustrated in FIG. 2G, during the CMP process the second upper surface and portion 235a and 235b may be removed.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming metallization in a semiconductor device, the method comprising:
forming an interlayer insulation layer on a semiconductor layer;
forming a hole in the interlayer insulation layer by removing a portion of the interlayer insulation layer;
forming a metal seed layer in the hole and on an upper surface of the interlayer insulation layer, such that the metal seed layer includes a first portion on the upper surface of the interlayer insulation layer, a second portion on an upper side surface of the hole, and a third portion on central and lower side surfaces of the hole;
selectively plasma-treating a portion of the metal seed layer;
forming a metal layer on the metal seed layer to fill the hole; and
forming metallization by polishing the metal layer.

2. The method as claimed in claim 1, wherein selectively plasma-treating a portion of the metal seed layer includes plasma-treating the first portion of the metal seed layer on the upper surface of the interlayer insulation layer, the upper surface of the interlayer insulation layer facing away from the semiconductor layer.

3. The method as claimed in claim 2, wherein selectively plasma-treating a portion of the metal seed layer includes plasma-treating the second portion of the metal seed layer on the upper side surface of the hole, a length of the second portion in the hole being substantially shorter than a length of the third portion in the hole.

4. The method as claimed in claim 1, wherein selectively plasma-treating a portion of the metal seed layer includes plasma-treating only the first and second portions of the metal seed layer before forming the metal layer.

5. The method as claimed in claim 1, wherein the plasma treatment is performed using a nitrogen containing gas.

6. The method as claimed in claim 5, wherein using the nitrogen containing gas includes using N₂, N₂H₄, NH₃, or a mixture thereof.

7. The method as claimed in claim 5, wherein the nitrogen containing gas has a flux in a range of about 1 sccm to about 50 sccm.

8. The method as claimed in claim 5, wherein the plasma treatment is performed using an inert gas with a flux in a range of about 1 sccm to about 20 sccm.

9. The method as claimed in claim 1, wherein the plasma treatment is performed with a radio frequency (RF) voltage in a range of about 1 W to about 2000 W.

10. The method as claimed in claim 1, wherein the plasma treatment is performed without applying a bias voltage to the semiconductor layer, or by applying a bias voltage of about 250 W or less to the semiconductor layer.

11. The method as claimed in claim 1, further comprising forming a barrier layer between the interlayer insulation layer and the metal seed layer.

12. The method as claimed in claim 11, wherein the barrier layer is formed of Ta and/or TaN.

13. The method as claimed in claim 1, wherein at least one of the metal seed layer and the metal layer is formed of one or more of Cu, Pt, Pd, Ni, Au, Ag, Ru, and an alloy thereof.

14. The method as claimed in claim 1, wherein the metal layer is formed using an electroplating process.

15. The method as claimed in claim 1, wherein:
forming the interlayer insulation layer includes sequentially stacking first and second interlayer insulation layers on the semiconductor layer;
forming the hole includes sequentially forming a via and a trench in the first and second interlayer insulation layers, respectively,
wherein the metal seed layer is formed to include the first portion on upper surfaces of the first and second interlayer insulation layers, the second portion on upper side surfaces of each of the trench and via, and the third portion on central and lower side surfaces of each of the trench and via.

16. A method of forming metallization in a semiconductor device, the method comprising:
forming an interlayer insulation layer on a semiconductor layer;
forming a hole in the interlayer insulation layer by removing a portion of the interlayer insulation layer;
forming a metal seed layer on a bottom surface and side surfaces of the hole and on an upper surface of the interlayer insulation layer;
plasma-treating a portion of the metal seed layer;
forming a metal layer on the metal seed layer to fill the hole; and
forming metallization by polishing the metal layer,
wherein the plasma treatment is performed using a nitrogen containing gas having a flux in a range of about 1 sccm to about 50 sccm and an inert gas having a flux in a range of about 1 sccm to about 20 sccm,
wherein the plasma treatment is performed with an RF voltage in a range of about 1 W to about 2000 W, and
wherein the plasma treatment is performed without applying a bias voltage to the semiconductor layer or by applying a bias voltage of 250 W or less to the semiconductor layer.

17. A method of forming metallization in a semiconductor device, the method comprising:
forming an interlayer insulation layer on a semiconductor layer;
forming a trench and a via in the interlayer insulation layer by removing portions of the interlayer insulation layer;
forming a metal seed layer on side surfaces of the interlayer insulation layers, which are exposed by the trench and the via, and on upper surfaces of the interlayer insulation layer;
plasma-treating a portion of the metal seed layer;
forming a metal layer on the metal seed layer to fill the hole; and
forming metallization by polishing the metal layer.

18. The method as claimed in claim 17, wherein plasma-treating includes plasma-treating a portion of the metal seed layer formed on the upper surfaces of the interlayer insulation layer.

19. The method as claimed in claim 17, wherein plasma-treating includes plasma-treating upper portions of the metal seed layer formed on the side surfaces of the interlayer insulation layer exposed by each of the trench and the via.

20. The method as claimed in claim 17, wherein the plasma treatment is performed using a nitrogen containing gas having a flux in a range of about 1 sccm to about 50 sccm, and an inert gas having a flux in a range of about 1 sccm to about 20 sccm,
wherein the plasma treatment is performed with an RF voltage in a range of about 1 W to about 2000 W, and
wherein the plasma treatment is performed without applying a bias voltage to the semiconductor layer or by applying a bias voltage of about 250 W or less to the semiconductor layer.
